(19) United States
(12) Patent Application Publication
(10) Pub. No.: US 2026/0266920 A1
(43) Pub. Date: Sep. 10, 2026

(54) BATTERY DIAGNOSTIC APPARATUS, BATTERY DIAGNOSTIC METHOD, AND BATTERY DIAGNOSTIC SYSTEM

(71) Applicants: Hyundai Motor Company, Seoul (KR); Kia Corporation, Seoul (KR)

(72) Inventors: Yo Han BAEK, Hwaseong-Si (KR); Bo Hyun LEE, Hwaseong-Si (KR)

(21) Appl. No.: 19/317,498

(22) Filed: Sep. 3, 2025

(30) Foreign Application Priority Data
Mar. 10, 2025 (KR) 10-2025-0030891

(51) Int. Cl. G01R 31/392; B60L 58/16; G01R 31/36; G01R 31/3842; G01R 31/396

(52) U.S. Cl. CPC G01R 31/392; B60L 58/16; G01R 31/3646; G01R 31/3842; G01R 31/396

(57) ABSTRACT

A battery diagnostic apparatus and a method thereof are provided. The battery diagnostic apparatus includes a communication device that obtains current data of a battery in a first charging interval and a second charging interval different from the first charging interval and a controller that calculates a first capacity of each of a plurality of battery cells included in the battery based on the current data in the first charging interval, calculates a second capacity of each of the plurality of battery cell based on the current data in the second charging interval, and diagnoses whether abnormality occurs in the plurality of battery cells based on comparison between the first capacity and the second capacity.

### CROSS-REFERENCE TO RELATED APPLICATION

This application claims priority to Korean Patent Application No. 10-2025-0030891, filed in the Korean Intellectual Property Office on Mar. 10, 2025, the entire contents of which are incorporated herein by reference.

### TECHNICAL FIELD

The present disclosure relates to a battery diagnostic apparatus, a battery diagnostic method, a battery diagnostic system.

### BACKGROUND

A battery (e.g., a vehicle battery) may be configured to store and supply electric energy to a load via a current flow between a cathode of the battery and an anode of the battery and may be used in various application fields, such as an electric vehicle (EV) and an energy storage system (ESS).

There is a possibility of an unintended leakage current between the cathode and the anode, due to one or more problems, such as a manufacturing defect occurring in a battery cell manufacturing process or a progressive defect in use. Such a leakage current is a phenomenon in which a micro-current flows in the inside except for an external electric circuit path which connects the cathode and the anode, which may cause a deterioration in battery performance and a safety problem.

The matters described in this Background section are only for enhancement of understanding of the background of the disclosure, and should not be taken as acknowledgement that they correspond to prior art already known to those skilled in the art.

### SUMMARY

The present disclosure has been made to solve the above-mentioned problems. The following summary presents a simplified summary of certain features. The summary is not an extensive overview and is not intended to identify key or critical elements.

An aspect of the present disclosure provides a battery diagnostic apparatus for diagnosing whether an individual battery cell is abnormal during charging and a method thereof.

Another aspect of the present disclosure provides a battery diagnostic apparatus for discriminating between an over-capacity cell due to a manufacturing deviation and an abnormal cell due to a leak current and a method thereof.

The technical problems to be solved by the present inventive concept are not limited to the aforementioned problems, and any other technical problems not mentioned herein will be clearly understood from the following description by those skilled in the art to which the present disclosure pertains.

Diagnosing abnormality in battery cell may be performed. Particularly, performing a battery diagnosis even in a load state as well as a no-load state and detecting abnormality in battery cells may be performed to improve accuracy of the diagnosis.

A battery diagnostic apparatus for a vehicle may comprise: a communication interface configured to obtain, via at least one sensor, first current data of a battery in a first charging interval and second current data of the battery in a second charging interval different from the first charging interval, wherein each of the first current data and the second current data is based on current flow measurements of a plurality of battery cells included in the battery; and a controller configured to: determine a first capacity of each of the plurality of battery cells based on the first current data in the first charging interval, determine a second capacity of each of the plurality of battery cells based on the second current data in the second charging interval, and generate, based on a comparison of the first capacities and the second capacities, a signal indicating at least one abnormal cell of the plurality of battery cells.

The controller may be configured to: determine a first standardization value based on an average value of the first capacities; determine a second standardization value based on an average value of the second capacities; and select a diagnosis target cell based on the first standardization value and the second standardization value.

The controller may be configured to: select, based on both the first standardization value and the second standardization value of an outlier cell of the plurality of battery cells being greater than or equal to a reference value, the outlier cell as the diagnosis target cell; and diagnose whether the diagnosis target cell is abnormal based on a comparison between the first capacity and the second capacity of the diagnosis target cell.

The controller may be configured to: determine a first relative value of the diagnosis target cell, the first relative value being relative to the average value of the first capacities; determine a second relative value of the diagnosis target cell, the second relative value being relative to the average value of the second capacities; and compare the first relative value with the second relative value to diagnose whether the diagnosis target cell is abnormal.

The controller may be configured to: determine that the diagnosis target cell is an abnormal cell, based on the first relative value being greater than the second relative value, wherein a state of charge (SOC) of the battery during the first charging interval is higher than an SOC of the battery during the second charging interval.

The controller may be configured to: determine the first capacities, using Ampere-hour counting, based on the first current data; and determine the second capacities, using Ampere-hour counting, based on the second current data. State of charge (SOC) values of the first charging interval may be greater than SOC values of the second charging interval.

A battery diagnostic method performed by a battery diagnostic apparatus may comprise: obtaining, via at least one sensor, first current data of a battery in a first charging interval and second current data of the battery in a second charging interval different from the first charging interval, wherein each of the first current data and the second current data is based on current flow measurements of a plurality of battery cells included in the battery; determining a first capacity of each of the plurality of battery cells based on the first current data in the first charging interval; determining a second capacity of each of the plurality of battery cells based on the second current data in the second charging interval; and generating, based on a comparison of the first capacities and the second capacities, a signal indicating at least one abnormal cell of the plurality of battery cells.

A battery diagnostic system for a vehicle may comprise: a battery including a plurality of battery cells; a sensor configured to obtain first current data of the battery in a first charging interval and second current data of the battery in a second charging interval different from the first charging interval, wherein each of the first current data and the second current data is based on current flow measurements of the plurality of battery cells; and a battery diagnostic apparatus configured to: identify, based on the first current data, at least one first outlier cell of the plurality of battery cell; identify, based on the second current data, at least one second outlier cell of the plurality of battery cell; identify, based on a comparison between the first current data and the second current data, at least one abnormal cell, wherein each of the at least one abnormal cell is one of the at least one first outlier cell corresponding to one of the at least one second outlier cell; and generate a signal indicating the at least one abnormal cell.

The battery diagnostic apparatus may be configured to: receive, from the sensor, the first current data and the second current data; determine a first capacity of each of the plurality of battery cells based on the first current data; determine a second capacity of each of the plurality of battery cells based on the second current data; and identify, based on a comparison of the first capacities and the second capacities, the at least one abnormal cell.

The battery diagnostic apparatus may be configured to: determine a first relative value of the first capacity of an outlier cell and a second relative value of the second capacity of the outlier cell; and diagnose whether the outlier cell is an abnormal cell based on a comparison between the first relative value and the second relative value.

The battery diagnostic apparatus may be configured to: determine a first capacity of each of the plurality of battery cells, using Ampere-hour counting, based on the first current data in a first voltage range which is common among voltage ranges of the plurality of battery cells in the first charging interval; and determine a second capacity of each of the plurality of battery cells, using Ampere-hour counting, based on the second current data in a second voltage range which is common among voltage ranges of the plurality of battery cells in the second charging interval.

The battery diagnostic apparatus may be configured to: determine a first standardization value based on an average value associated with the first capacities; determine a second standardization value based on an average value associated with the second capacities; and select, based on both the first standardization value and the second standardization value of an outlier cell being greater than or equal to a relative value, the outlier cell as a diagnosis target cell.

The battery diagnostic apparatus may be configured to: compare the first relative value with the second relative value to diagnose whether the outlier cell is abnormal.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating a configuration of a battery diagnostic system;

FIG. 2 is a block diagram illustrating a configuration of a battery diagnostic apparatus;

FIG. 3 is a graph illustrating a first relative value and a first standardization value;

FIG. 4 is a graph illustrating a second relative value and a second standardization value;

FIG. 5 is a flowchart illustrating a battery diagnostic method;

FIG. 6 is a flowchart illustrating a battery diagnostic method; and

FIG. 7 is a block diagram illustrating a computing system for executing a battery diagnostic method.

### DETAILED DESCRIPTION

Hereinafter, various features and examples of the present disclosure will be described in detail with reference to the accompanying drawings. In order to clearly describe the present disclosure, parts that are irrelevant to the description are omitted, identical or similar constituent components throughout the present disclosure are denoted by the same reference numerals, and the duplicated description is omitted.

Furthermore, various features and examples of the present disclosure may be implemented/executed in many different forms and should not be construed as being limited to the features and examples described in the present disclosure. Various features and examples of the present disclosure and terms used herein are not intended to limit the technologies described in the present disclosure to specific embodiment(s), and it should be understood that the embodiment(s) and the terms include modification, equivalent, and/or alternative.

In describing various features of the present disclosure, the terms first, second, A, B, (a), (b), and the like may be used herein. These terms are only used to distinguish one component from another component, but do not limit the corresponding components irrespective of the order or priority of the corresponding components.

According to various features and examples of the present disclosure, each component may include a singular entity or a plurality of entities and some of the plurality of entities may be separated arranged in another component. According to various features and examples, one or more of the above-mentioned components or steps may be omitted or one or more other components or operations may be added. Furthermore, according to various features and examples, a plurality of components may be integrated into one component. In this case, the integrated component may perform one or more functions of each of the plurality of components in the same or similar manner to being performed by the corresponding component among the plurality of components prior to the integration. According to various features and examples of the present disclosure, operations performed by a module, a program, or another component may be executed sequentially, in parallel, or repeatedly, one or more of the operations may be executed in another order, or one or more other operations may be added.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as "A, B, or C", "at least one of A, B, and C", "at least one of A, B, or C", etc. as used herein may mean each listed item or all possible combinations of the listed items. For example, "at least one of A or B" may refer to (1) at least one A; (2) at least one B; or (3) at least one A and at least one B.

The term “module” or “unit” used in the specification means a software and/or hardware component, and the “module” or “unit” performs certain operations/functions/roles. However, the “module” or “unit” is not construed as being limited to software or hardware. The “module” or “unit” may be configured to be in an addressable storage medium or to execute one or more processors. Therefore, as an example, the “module” or “unit” may include at least one of components such as software components, object-oriented software components, class components, and task components, processes, functions, attributes, procedures, sub-routines, segments of program codes, drivers, firmware, micro-codes, circuits, data, databases, data structures, tables, arrays, or variables. Functions provided in the components, “modules” or “units” may be combined into a smaller number of components, “modules” or “units” or further divided into additional components, “modules” or “units”.

In the present disclosure, the “module,” “device,” or “unit,” etc. may be realized as a processor and a memory. The “processor” should be widely construed to include a general-purpose processor, a central processing unit (CPU), a microprocessor, a digital signal processor (DSP), a microcontroller, a state machine, or the like. In some environments, the “processor” may refer to an application-specific integrated circuit (ASIC), a programmable logic device (PLD), or a field-programmable gate array (FPGA), and the like. For example, the “processor” may refer to a combination of processing devices such as a combination of a DSP and a microprocessor, a combination of a plurality of microprocessors, a combination of one or more microprocessors combined with a DSP core, or any other such combination. Moreover, the “memory” should be widely construed to include any electronic component capable of storing electronic information. The “memory” may refer to various types of processor-readable medium such as a random access memory (RAM), a read only memory (ROM), a non-volatile random access memory (NVRAM), a programmable read only memory (PROM), an erasable programmable read only memory (EPROM), an electrically erasable programmable read only memory (EEPROM), a flash memory, a magnetic or optical data storage device, and registers. When the processor can read information from a memory and/or record the information in the memory, the memory may be in a state of electronic communication with a processor. Memory integrated into a processor is in a state of electronic communication with the processor.

The one or more features described herein may be provided as a computer program stored in a computer-readable recording medium in order to be executed on a computer. The medium may either continuously store a computer-executable program or temporarily store the program for execution or download. Furthermore, the medium may be a variety of recording or storage means in the form of a single hardware device or multiple combined hardware devices, and is not limited to media directly connected to some computer system but may also be distributed across a network. Examples of such media include magnetic media such as a hard disk, a floppy disk, or a magnetic tape, optical recording media such as a CD-ROM or a DVD, magneto-optical media such as a floptical disk, and a ROM, RAM, or flash memory, among others, configured to store program instructions. Additional examples of such media include media or storage media that are managed by an app store that distributes applications or by various other sites or servers that provide or distribute software.

In a hardware implementation, processing units used for performing the techniques may be implemented within one or more ASICs, DSPs, digital signal processing devices, programmable logic devices, field-programmable gate arrays, processors, controllers, microcontrollers, microprocessors, electronic devices, or computers or combinations thereof designed to perform the functions described in the present disclosure.

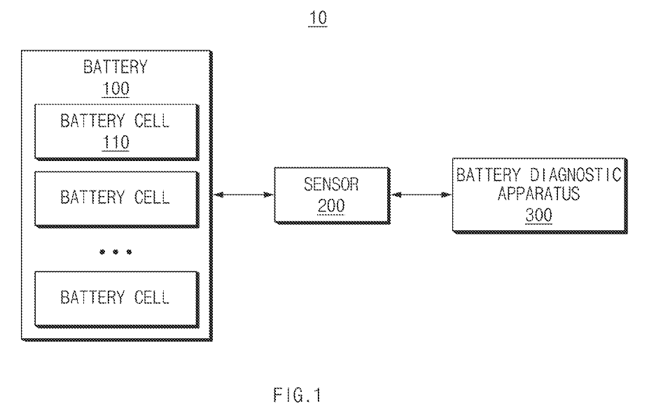

Hereinafter, features and examples of the present disclosure will be described in detail with reference to FIGS. 1 to 7.

FIG. 1 is a block diagram illustrating a configuration of a battery diagnostic system.

Referring to FIG. 1, a battery diagnostic system 10 (e.g., a battery management system) may include a battery 100, a sensor 200, and a battery diagnostic apparatus 300. The battery diagnostic system 10 may be implemented in a vehicle. Some of the components of the battery diagnostic system 10 may be implemented inside the vehicle and the others may be implemented outside the vehicle.

The battery 100 may receive a diagnosis of whether an individual battery cell 110 is abnormal by the battery diagnostic apparatus 300 in a state in which it is loaded into the vehicle. As another example, the battery 100 may receive a diagnosis indication indicating whether the individual battery cell 110 is abnormal by the battery diagnostic apparatus 300 in a state in which it is not loaded into the vehicle. One or more battery cells may be abnormal, for example, one or more parameters of the battery cell(s) are not within a specific range (e.g., an overvoltage, an undervoltage, an overtemperature, an under temperature, high internal resistance, etc.), an internal short circuit, battery swelling, capacity deterioration, and/or electrolyte leakage, etc.

The battery 100 may include a plurality of battery cells 110. For example, the battery 100 may include the plurality of battery cells 110 which are connected with each other in serial or in parallel.

The sensor 200 may obtain data by measuring an electrical characteristic of the battery 100. In an example, the sensor 200 may include at least one of a current sensor, a voltage sensor, and/or a resistance sensor. The sensor 200 may obtain data by measuring at least one of a current, a voltage, and/or resistance of the battery 100.

The sensor 200 may obtain current data of the battery 100 in a first charging interval and a second charging interval different from the first charging interval. Herein, the first charging interval and the second charging interval may refer to different state of charge (SOC) ranges of the battery 100.

The first charging interval may be defined as an SOC range greater than an SOC range corresponding to the second charging interval. For example, the first charging interval may be defined as an SOC range of 80-100% and the second charging interval may be defined as an SOC range of 60-80%. However, because this is only an example, the first charging interval and the second charging interval of the present disclosure are not limited thereto.

The sensor 200 may transmit the current data of the battery 100 to the battery diagnostic apparatus 300. For example, the sensor 200 may transmit the current data of the battery 100 to the battery diagnostic apparatus 300 via wired or wireless communication.

The battery diagnostic apparatus 300 may perform operations for diagnosing the battery cell 110 in which abnormality (e.g., battery cell abnormality) occurs among the plurality of battery cells 110 included in the battery 100. For example, the battery diagnostic apparatus 300 may be implemented in the form of at least one of a battery management system (BMS), diagnostic equipment (e.g., a personal computer (PC), a global diagnostic system (GDS), or the like), and/or a cloud computing system.

The battery diagnostic apparatus 300 may obtain the current data of the battery 100 from the sensor 200. For example, the battery diagnostic apparatus 300 may receive the current data from the sensor 200 via wired or wireless communication.

The battery diagnostic apparatus 300 may calculate a first capacity of each of the plurality of battery cells 110 included in the battery 100 based on the current data in the first charging interval. The battery diagnostic apparatus 300 may calculate a second capacity of each of the plurality of battery cells 110 included in the battery 100 based on the current data in the second charging interval different from the first charging interval.

The battery diagnostic apparatus 300 may calculate the first capacity of each of the plurality of battery cells 110 based on the current data of the battery 100 in a first voltage range which is common among voltage ranges of the plurality of battery cells 110 in the first charging interval. The battery diagnostic apparatus 300 may calculate the second capacity of each of the plurality of battery cells 110 based on the current data of the battery 100 in a second voltage range which is common among the voltage ranges of the plurality of battery cells 110 in the second charging interval.

For example, the battery diagnostic apparatus 300 may calculate the first capacity of each of the plurality of battery cells 110 using Ampere-hour counting (Ah-counting) based on the current data of the battery 100 in the first charging interval. The present invention utilizes an Ampere-hour counting (Ah-counting) method to estimate the capacity of a battery. Ah-counting refers to a technique of calculating the amount of charge charged into or discharged from a battery cell by integrating the current (in amperes) over time (in hours) during a specific charging or discharging interval, resulting in a value expressed in ampere-hours (Ah).

According to the present invention, the battery diagnostic apparatus calculates a first capacity and a second capacity of each of a plurality of battery cells based on current data obtained during two different charging intervals using the Ah-counting method. Based on the calculated capacities, the apparatus determines statistical indicators such as an average value, standard deviation, and z-score to assess the uniformity or degradation state of the battery cells. The Ah-counting may include integrating the current flowing into or out of the battery (e.g., a battery cell) over time to calculate how much charge has been used or added. The battery diagnostic apparatus 300 may calculate the second capacity of each of the plurality of battery cells 110 using the Ah-counting based on the current data in the second charging interval.

The battery diagnostic apparatus 300 may calculate a first standardization value (e.g., a standard deviation) of the first capacity and a second standardization value (e.g., a standard deviation) of the second capacity. In an example, the first standardization value may include a deviation or a z-score calculated based on an average value of the first capacities. The second standardization value may include a deviation or a z-score calculated based on an average value of the second capacities.

The battery diagnostic apparatus 300 may select the battery cell 110 satisfying a condition (e.g., having both the first standardization value and the second standardization value are greater than or equal to a reference value) as a diagnosis target cell. Thus, the battery diagnostic apparatus 300 may diagnose whether the diagnosis target cell is abnormal based on a comparison between the first capacity and the second capacity of the diagnosis target cell.

The battery diagnostic apparatus 300 may calculate a first relative value of the first capacity based on the average value of the first capacities. For example, the first relative value may refer to a value obtained by converting the first capacity of each of the plurality of battery cells 110 into a percentage based on the average value of the first capacities.

The battery diagnostic apparatus 300 may calculate a second relative value of the second capacity based on the average value of the second capacities. The second relative value may refer to a value obtained by converting the second capacity of each of the plurality of battery cells 110 into a percentage based on the average value of the second capacities.

The battery diagnostic apparatus 300 may compare the first relative value of the diagnosis target cell with the second relative value of the diagnosis target cell to diagnose whether the diagnosis target cell is abnormal. For example, if the first relative value is greater than the second relative value, the battery diagnostic apparatus 300 may diagnose that the diagnosis target cell is abnormal.

In other words, if the over-capacity level of the battery cell increases as the voltage range increases, the battery diagnostic apparatus 300 may diagnose the battery cell as an abnormal cell due to a current leakage rather than an over-capacity cell by a manufacturing irregularities (e.g., unintended deviations from standard specifications, manufacturing processes, or quality expectations during the manufacturing processes). As a result, the battery diagnostic apparatus 300 may distinguish an over-capacity cell that is abnormal due to a capacity deviation in a manufacturing process from an abnormal cell that is abnormal due to a current leakage.

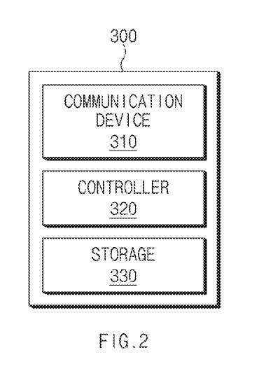

FIG. 2 is a block diagram illustrating a configuration of a battery diagnostic apparatus.

Referring to FIG. 2, a battery diagnostic apparatus 300 may include a communication device 310 (e.g., a communication interface, a transceiver, and/or other wired and wireless modems, etc.), a controller 320 (e.g., a processor, a memory, etc.), and storage 330.

The communication device 310 may include a communication circuit capable of communicating with another electronic device. In an example, the communication device 310 may perform wired or wireless communication with the other electronic device to transmit and receive data. For example, the communication device 310 may perform wired or wireless communication to obtain at least one of current data, voltage data, or resistance data of the battery 100 from a sensor 200.

The communication device 310 may obtain current data of the battery 100 in a first charging interval and a second charging interval different from the first charging interval from the sensor 200. For example, the communication device 310 may obtain current data in which the sensor 200 measures a current of the battery 100 at a (e.g., constant) time interval in the first charging interval and the second charging interval included in a charging process of the battery 100 from the sensor 200.

The controller 320 may execute instructions stored in the storage 330 to control an operation of the battery diagnostic apparatus 300. For example, the controller 320 may include a processor for executing at least one instruction stored in the storage 330.

The controller 320 may calculate a first capacity of each of a plurality of battery cells 110 based on the current data in the first charging interval. For example, the controller 320 may calculate the first capacity of each of the plurality of battery cells 110 using Ah-counting based on the current data in the first charging interval.

The controller 320 may calculate the first capacity of each of the plurality of battery cells 110 based on the current data of the battery 100 in a first voltage range which is common among voltage ranges of the plurality of battery cells 110 in the first charging interval. For example, the controller 320 may calculate the first capacity of each of the plurality of battery cells 110 using the Ah-counting based on the current data of the battery 100 in the first charging interval.

For example, if voltage ranges of a first battery cell, a second battery cell, and a third battery cell are a range of 3.0-4.0 V, a range of 3.2-3.8 V, and a range of 3.4-3.6 V in the first charging interval, respectively, the controller 320 may use the range of 3.4-3.6 V, which is common to each battery cell, as the first voltage range to calculate the first capacity. The controller 320 may calculate first capacities of the first battery cell, the second battery cell, and the third battery cell using the Ah-counting based on the current data of the battery 100 in the range of 3.4-3.6 V.

The controller 320 may calculate a second capacity of each of the plurality of battery cells 110 based on the current data in the second charging interval. For example, the controller 320 may calculate the second capacity of each of the plurality of battery cells 110 using the Ah-counting based on the current data in the second charging interval.

The controller 320 may calculate the second capacity of each of the plurality of battery cells 110 based on the current data of the battery 100 in a second voltage range which is common among voltage ranges of the plurality of battery cells 110 in the second charging interval. For example, the controller 320 may calculate the second capacity of each of the plurality of battery cells 110 using the Ah-counting based on the current data of the battery 100 in the second voltage range.

For example, if voltage ranges of the first battery cell, the second battery cell, and the third battery cell are the range of 3.0-4.0 V, the range of 3.2-3.8 V, and the range of 3.4-3.6 V in the second charging interval, respectively, the controller 320 may use the range of 3.4-3.6 V, which is common to each battery cell, as the second voltage range to calculate the second capacity. The controller 320 may calculate second capacities of the first battery cell, the second battery cell, and the third battery cell using the Ah-counting based on the current data of the battery 100 in the range of 3.4-3.6 V.

The example numerical values of the first voltage range and the second voltage range are exemplary, and aspects of the present disclosure is not limited thereto.

The controller 320 may calculate a second relative value of the first capacity, which is relative to an average value of the first capacities, and may calculate a second relative value of the second capacity, which is relative to an average value of the second capacities. For example, the controller 320 may convert the first capacity into a percentage value based on the average value of the first capacities to calculate the first relative value. The controller 320 may convert the second capacity into a percentage value based on the average value of the second capacities to calculate the second relative value.

The controller 320 may calculate a first standardization value of the first capacity and a second standardization value of the second capacity. In detail, the first standardization value may include a deviation or a z-score calculated based on the first capacity. The second standardization value may include a deviation or a z-score calculated based on the second capacity.

For example, the controller 320 may calculate a deviation of the first capacity of each of the plurality of battery cells 110 as the first standardization value based on the average value of the first capacities of the plurality of battery cells 110. The controller 320 may calculate a deviation of the second capacity of each of the plurality of battery cells 110 as the second standardization value based on the average value of the second capacities of the plurality of battery cells 110.

For example, the controller 320 may calculate a z-score of the first capacity of each of the plurality of battery cells 110 as the first standardization value based on the average value of the first capacities of the plurality of battery cells 110. The controller 320 may calculate a z-score of the second capacity of each of the plurality of battery cells 110 as the second standardization value based on the average value of the second capacities of the plurality of battery cells 110.

For example, the controller 320 may calculate a first standardization value of each of the plurality of battery cells 110 based on an average value of first relative values of the plurality of battery cells 110. The controller 320 may calculate a second standardization value of each of the plurality of battery cells 110 based on an average value of second relative values of the plurality of battery cells 110.

In this case, the controller 320 may calculate a deviation or a z-score of the first relative value as the first standardization value based on the average value of the first relative values of the plurality of battery cells 110. The controller 320 may calculate a deviation or a z-score of the second relative value as the second standardization value on the basis of the average value of the second relative values of the plurality of battery cells 110.

The controller 320 may select the battery cell 110 satisfying a condition (e.g., having both the first standardization value and the second standardization value are greater than or equal to a reference value) as a diagnosis target cell. For example, if the reference value is 5, the controller 320 may select the battery cell 110, having both the first standardization value and the second standardization value greater than or equal to 3, as the diagnosis target cell. However, the magnitude of the reference value described above is exemplary, and may be differently set according to an environment which implements the present disclosure, and aspect of the present disclosure is not limited thereto.

The controller 320 may compare the first relative value of the diagnosis target cell with the second relative value of the diagnosis target cell to diagnose whether the diagnosis target cell is abnormal. For example, if the first relative value of the diagnosis target cell is greater than the second relative value of the diagnosis target cell, the controller 320 may diagnose that abnormality due to a current leakage in the diagnosis target cell. For example, if the first relative value of the diagnosis target cell is less than or equal to the second relative value of the diagnosis target cell, the controller 320 may diagnose the diagnosis target cell as a normal cell and an over-capacity cell that is abnormal due to a manufacturing irregularities.

In other words, the over-capacity cell that is abnormal due to the manufacturing irregularities has a relatively small change in the relative capacity value for another battery cell although its voltage increases, whereas the abnormal cell that is abnormal due to the current leakage has a relatively greater change in the relative capacity value for the other battery cell, because the current leakage rate increases if its voltage increases.

As a result, the battery diagnostic apparatus 300 may simply and clearly diagnose whether the battery cell is an over-capacity cell that is abnormal due to the manufacturing deviation or an abnormal cell that is abnormal due to a current leakage based on the current data of the battery cell, which is obtained during a charging process.

The storage 330 may be one or more storage devices for storing all types of data and algorithms described herein. For example, the storage 330 may store a battery diagnostic algorithm, a past diagnostic history, data obtained from the sensor 200, and the calculated result of the controller 320.

For example, if the battery diagnostic apparatus 300 is implemented as a battery management unit or diagnostic equipment mounted on a vehicle, the storage 330 may temporarily or permanently store data using a volatile and/or non-volatile storage device.

For another example, if the battery diagnostic apparatus 300 is implemented in the form of a cloud computing system, the storage 330 may store data using a distributed storage system or a cloud database accessible over a network. In this case, the storage 330 may store current data obtained from the sensor 200 in a cloud server and may interwork with a database management system to perform a storage and search function.

The storage 330 may store the current data of the battery 100, which is obtained from the sensor 200. The storage 330 may store the first capacity and the second capacity of each of the plurality of battery cells 110, which are calculated in the first charging interval and the second charging interval. The storage 330 may store reference values for the first standardization value and the second standardization value.

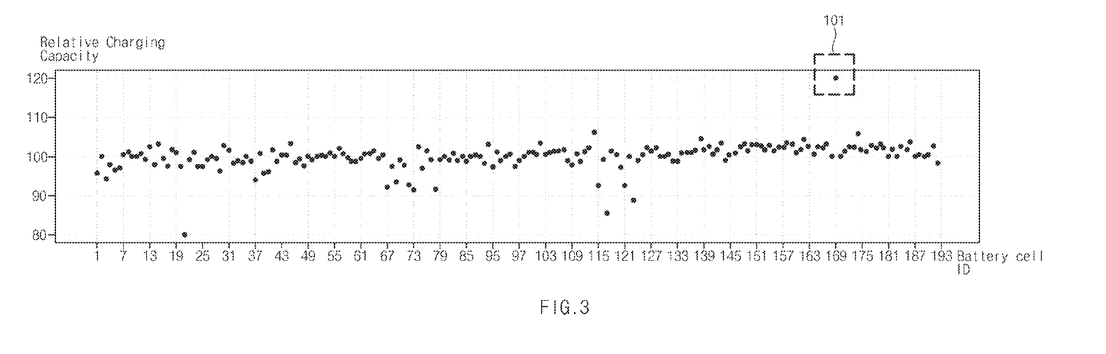

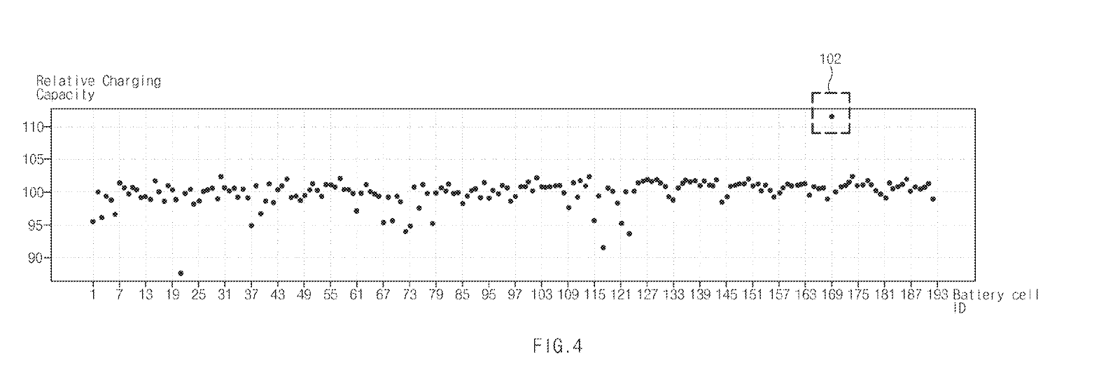

Hereinafter, a description will be given of an abnormality diagnostic method with reference to FIGS. 3 and 4.

FIG. 3 is a graph illustrating a first relative value and a first standardization value. FIG. 4 is a graph illustrating a second relative value and a second standardization value.

FIG. 3 is a graph illustrating a first relative value of each of a plurality of battery cells 110. The horizontal axis indicates the battery cell 110’s number (e.g., an identifier of a battery cell) and the vertical axis indicates the first relative value of the battery cell 110 (e.g., a relative charging capacity of a battery cell). As described above, the first relative values are measured in the first charging interval (e.g., the SOC of the battery comprising the battery cells 100 is in a first range).

The controller 320 may calculate the first relative value of each of the plurality of battery cells 110 based on an average value of first capacities of the plurality of battery cells 110. For example, the controller 320 may convert the first capacity of each of the plurality of battery cells 110 into a percentage value based on the average value of the first capacities of the plurality of battery cells 110 to calculate the first relative value. For example, as shown in FIG. 3, the first capacity of each of 192 battery cells 110 may be measured. The first capacities of the 192 battery cells 110 may correspond to the charging capacities of the 192 battery cells 100 in the first charging interval. The average value of the first capacities of the 192 battery cells 110 may be calculated. The average value of the first capacities of the 192 battery cells 110 corresponds to 100% in the vertical axis of FIG. 3. Each of the first capacities of the 192 battery cells 110 may be converted to a first relative value. If the first capacities of the 192 battery cells 110 are higher than the average value of the first capacities of the 192 battery cells 110, the first relative values of those battery cells are higher than 100%. If the first capacities of the 192 battery cells 110 are lower than the average value of the first capacities of the 192 battery cells 110, the first relative values of those battery cells are lower than 100%. For No. 169 battery cell 101 shown in FIG. 3, the controller 320 may calculate 120.0% obtained by converting the first capacity of No. 169 battery cell 101 into a percentage value, based on the average value of the first capacities, as the first relative value. If the first capacity of the battery cell is the same as the average value, the first relative value may be calculated as 100%.

The controller 320 may calculate a first standardization value of each of the plurality of battery cells 110 based on the average value of the first relative values. The controller 320 may select the battery cell satisfying a condition (e.g., having the first standardization value greater than or equal to a reference value). For example, if the reference value is 5, the controller 320 may select No. 169 battery cell 101, having the first standardization value greater than or equal to 5. As shown in FIG. 3, the No. 169 battery cell 101 is an outlier (e.g., an outlier cell) and satisfies the condition by having a relatively high first capacity than other battery cells. As described below, the No. 169 battery cell 101 may be determined as a diagnosis target cell.

FIG. 4 is a graph illustrating a second relative value of each of the plurality of battery cells 110. The horizontal axis indicates the battery cell 110’s number (e.g., an identifier of a battery cell) and the vertical axis indicates the second relative value of the battery cell 110 (e.g., a relative charging capacity of a battery cell). As described above, the second relative values are measured in the second charging interval (e.g., the SOC of the battery comprising the battery cells 100 is in a second range). The SOC level (e.g., an SOC range) of the battery, comprising the battery cells 110, in the second charging interval may be lower than the SOC level (e.g., an SOC range) of the battery in the first charging interval.

The controller 320 may calculate a second relative value of each of the plurality of battery cells 110 based on an average value of second capacities of the plurality of battery cells 110. For example, the controller 320 may convert the second capacity of each of the plurality of battery cells 110 into a percentage value based on the average value of the second capacities to calculate the second relative value. For example, as shown in FIG. 4, the second capacity of each of 192 battery cells 110 may be measured. The second capacities of the 192 battery cells 110 may correspond to the charging capacities of the 192 battery cells 100 in the second charging interval. The average value of the second capacities of the 192 battery cells 110 may be calculated. The average value of the second capacities of the 192 battery cells 110 corresponds to 100% in the vertical axis of FIG. 4. Each of the second capacities of the 192 battery cells 110 may be converted to a second relative value. If the second capacities of the 192 battery cells 110 are higher than the average value of the second capacities of the 192 battery cells 110, the second relative values of those battery cells are higher than 100%. If the second capacities of the 192 battery cells 110 are lower than the average value of the second capacities of the 192 battery cells 110, the second relative values of those battery cells are lower than 100%. For No. 169 battery cell 102 shown in FIG. 4, the controller 320 may calculate 111.4% obtained by converting the second capacity of No. 169 battery cell 102 into a percentage value, based on the average value of the second capacities, as the second relative value. If the second capacity of the battery cell is the same as the average value, the second relative value may be calculated as 100%.

The controller 320 may calculate a second standardization value of each of the plurality of battery cells 110 based on the average value of the second relative values. The controller 320 may select the battery cell satisfying a condition (e.g., having the second standardization value greater than or equal to the reference value). For example, if the reference value is 5, the controller 320 may select No. 169 battery cell 102, having the second standardization value greater than or equal to 5. As shown in FIG. 4, the No. 169 battery cell 102 is an outlier (e.g., an outlier cell) and satisfies the condition by having a relatively high second capacity than other battery cells. As described below, the No. 169 battery cell 102 may be determined as a diagnosis target cell.

The controller 320 may select the battery cell (e.g., the No. 169 battery cell), having both the first standardization value and the second standardization value greater than or equal to the reference value, as a diagnosis target cell. For example, if the reference value is 5, the controller 320 may select No. 169 battery cell, having both the first standardization value and the second standardization value greater than or equal to 5, as the diagnosis target cell.

If the first relative value (e.g., 120% as shown in FIG. 3) of the diagnosis target cell is greater than the second relative value (e.g., 111.4% as shown in FIG. 4) of the diagnosis target cell, the controller 320 may diagnose that an abnormality occurs in the diagnosis target cell. For example, because the first relative value of the diagnosis target cell is 120.0% and the second relative value of the diagnosis target cell is 111.4%, the controller 320 may diagnose that abnormality occurs in the diagnosis target cell because the first relative value, of the diagnosis target cell, measured in the first charging interval is higher than the second relative value, of the diagnosis target cell, measured in the second charging interval.

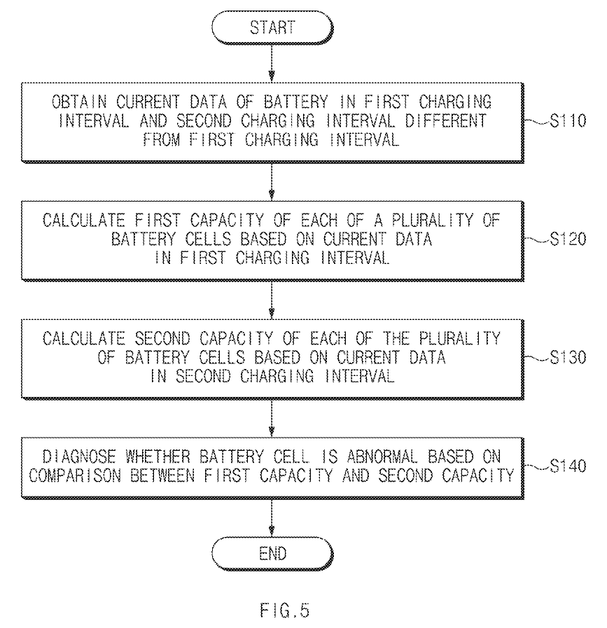

FIG. 5 is a flowchart illustrating a battery diagnostic method.

Hereinafter, it is assumed that a battery diagnostic apparatus 300 of FIGS. 1 and 2 performs respective steps. The respective steps of FIG. 5 may be sequentially performed, but are not necessarily sequentially performed in at least some implementations. For example, an order of the respective steps may be changed and a plurality of steps may be performed in parallel.

Referring to FIG. 5, in S110, a battery diagnostic apparatus 300 may obtain current data of a battery 100 in a first charging interval and a second charging interval different from the first charging interval.

For example, the first charging interval may be defined as a state of charge (SOC) range having an SOC level higher than an SOC level of an SOC range for the second charging interval. For example, if the first charging interval may correspond to an SOC range of 70%-80%, the second charging interval may correspond to an SOC range of 50%-60%, for example.

In S120, the battery diagnostic apparatus 300 may calculate a first capacity of each of a plurality of battery cells 110 based on the current data in the first charging interval.

For example, the battery diagnostic apparatus 300 may calculate the first capacity of each of the plurality of battery cells 110 using Ah-counting based on the current data in the first charging interval.

In S130, the battery diagnostic apparatus 300 may calculate a second capacity of each of the plurality of battery cells 110 based on the current data in the second charging interval.

For example, the battery diagnostic apparatus 300 may calculate the second capacity of each of the plurality of battery cells 110 using the Ah-counting based on the current data in the second charging interval.

In S140, the battery diagnostic apparatus 300 may diagnose whether the battery cell 110 is abnormal based on a comparison between the first capacity and the second capacity.

For example, the battery diagnostic apparatus 300 may calculate a first standardization value based on an average value of the first capacities and may calculate a second standardization value based on an average value of the second capacities.

For example, the battery diagnostic apparatus 300 may select a diagnosis target cell based on the first standardization value and the second standardization value. The battery diagnostic apparatus 300 may select the battery cell, having both the first standardization value and the second standardization value greater than or equal to a reference value, as the diagnosis target cell.

For example, the battery diagnostic apparatus 300 may diagnose whether the diagnosis target cell is abnormal based on a comparison between the first capacity and the second capacity of the diagnosis target cell.

For example, the battery diagnostic apparatus 300 may calculate a first relative value of the diagnosis target cell based on the average value of the first capacities and may calculate a second relative value of the diagnosis target cell based on the average value of the second capacities.

For example, the battery diagnostic apparatus 300 may compare the first relative value of the diagnosis target cell with the second relative value of the diagnosis target cell to diagnose whether the diagnosis target cell is abnormal. For example, if the first relative value is greater than the second relative value, the battery diagnostic apparatus 300 may diagnose that an abnormality occurs in the diagnosis target cell.

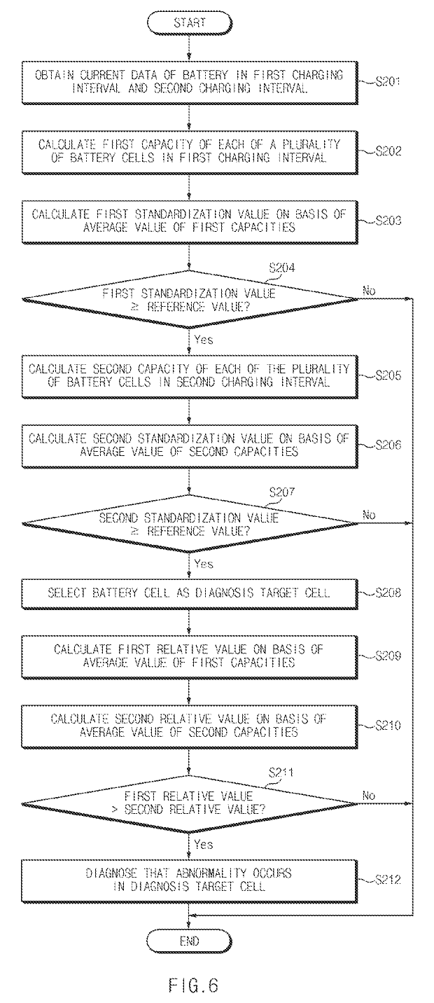

FIG. 6 is a flowchart illustrating a battery diagnostic method.

Hereinafter, it is assumed that a battery diagnostic apparatus 300 of FIGS. 1 and 2 performs respective operations of FIG. 6. Furthermore, in a description of FIG. 6, operations described as being performed by a battery diagnostic apparatus 300 may be understood as being controlled by a controller 320 included in the battery diagnostic apparatus 300.

Referring to FIG. 6, in S201, the battery diagnostic apparatus 300 may obtain current data of a battery 100 in a first charging interval and a second charging interval during a charging process. If obtaining the current data of the battery 100 in the first charging interval and the second charging interval during the charging process, the battery diagnostic apparatus 300 may perform S202.

In S202, the battery diagnostic apparatus 300 may calculate a first capacity of each of a plurality of battery cells 110 based on the current data in the first charging interval. If the battery diagnostic apparatus 300 determines to calculate the first capacity of each of the plurality of battery cells 110, the battery diagnostic apparatus 300 may perform S203.

In S203, the battery diagnostic apparatus 300 may calculate a first standardization value based on an average value of the first capacities of the plurality of battery cells 110. If the battery diagnostic apparatus 300 determines to calculate the first standardization value of each of the plurality of battery cells 110, the battery diagnostic apparatus 300 may perform S204.

In S204, the battery diagnostic apparatus 300 may determine whether the first standardization value is greater than or equal to a reference value. If the first standardization value of each of the plurality of battery cells 110 is less than the reference value, the battery diagnostic apparatus 300 may terminate the battery abnormality diagnosis. If there is at least one battery cell 110, having the first standardization value greater than or equal to the reference value, among the plurality of battery cells 110, the battery diagnostic apparatus 300 may perform S205.

In S205, the battery diagnostic apparatus 300 may calculate a second capacity of each of the plurality of battery cells 110 based on the current data in the second charging interval different from the first charging interval. If the battery diagnostic apparatus 300 determines to calculate the second capacity of each of the plurality of battery cells 110, the battery diagnostic apparatus 300 may perform S206.

In S206, the battery diagnostic apparatus 300 may calculate a second standardization value based on an average value of the second capacities of the plurality of battery cells 110. If the battery diagnostic apparatus 300 determines to calculate the second standardization value of each of the plurality of battery cells 110, the battery diagnostic apparatus 300 may perform S207.

In S207, the battery diagnostic apparatus 300 may determine whether the second standardization value is greater than or equal to the reference value. If the second standardization value of each of the plurality of battery cells 110 is less than the reference value, the battery diagnostic apparatus 300 may terminate the battery abnormality diagnosis. If there is at least one battery cell 110, having the second standardization value greater than or equal to the reference value, among the plurality of battery cells 110, the battery diagnostic apparatus 300 may perform S208.

In S208, the battery diagnostic apparatus 300 may select the battery cell, having both the first standardization value and the second standardization value greater than or equal to the reference value, as a diagnosis target cell. If the battery diagnostic apparatus 300 selects the diagnosis target cell, the battery diagnostic apparatus 300 may perform S209.

In S209, the battery diagnostic apparatus 300 may calculate a first relative value of the diagnosis target cell based on the average value of the first capacities. If the battery diagnostic apparatus 300 calculates the first relative value of the diagnosis target cell, the battery diagnostic apparatus 300 may perform S210.

In S210, the battery diagnostic apparatus 300 may calculate a second relative value of the diagnosis target cell based on the average value of the second capacities. If the battery diagnostic apparatus 300 calculates the second relative value of the diagnosis target cell, the battery diagnostic apparatus 300 may perform S211.

In S211, the battery diagnostic apparatus 300 may determine whether the first relative value of the diagnosis target cell is greater than the second relative value of the diagnosis target cell. If the first relative value of the diagnosis target cell is less than or equal to the second relative value of the diagnosis target cell, the battery diagnostic apparatus 300 may terminate the battery abnormality diagnosis. If the first relative value of the diagnosis target cell is greater than the second relative value of the diagnosis target cell, the battery diagnostic apparatus 300 may perform S212.

If the first relative value of the diagnosis target cell is greater than the second relative value of the diagnosis target cell, in S212, the battery diagnostic apparatus 300 may diagnose that an abnormality occurs in the diagnosis target cell. If the battery diagnostic apparatus 300 terminates the battery abnormality diagnosis as described above, the battery diagnostic apparatus 300 may determine that an abnormality associated with a current leakage has not been detected in any of the battery cells.

One or more features described herein may be used to control at least one autonomous driving control operation. A notification may be output by a vehicle (e.g., via a display, a speaker, etc.) to indicate at least one abnormal battery cell, for example, during autonomous driving operation of the vehicle.

An automation level of an autonomous driving vehicle may be classified as follows, according to the American Society of Automotive Engineers (SAE). At autonomous driving level 0, the SAE classification standard may correspond to “no automation,” in which an autonomous driving system is temporarily involved in emergency situations (e.g., automatic emergency braking) and/or provides warnings only (e.g., blind spot warning, lane departure warning, etc.), and a driver is expected to operate the vehicle. At autonomous driving level 1, the SAE classification standard may correspond to “driver assistance,” in which the system performs some driving functions (e.g., steering, acceleration, brake, lane centering, adaptive cruise control, etc.) while the driver operates the vehicle in a normal operation section, and the driver is expected to determine an operation state and/or timing of the system, perform other driving functions, and cope with (e.g., resolve) emergency situations. At autonomous driving level 2, the SAE classification standard may correspond to “partial automation,” in which the system performs steering, acceleration, and/or braking under the supervision of the driver, and the driver is expected to determine an operation state and/or timing of the system, perform other driving functions, and cope with (e.g., resolve) emergency situations. At autonomous driving level 3, the SAE classification standard may correspond to “conditional automation,” in which the system drives the vehicle (e.g., performs driving functions such as steering, acceleration, and/or braking) under limited conditions but transfer driving control to the driver when the required conditions are not met, and the driver is expected to determine an operation state and/or timing of the system, and take over control in emergency situations but do not otherwise operate the vehicle (e.g., steer, accelerate, and/or brake). At autonomous driving level 4, the SAE classification standard may correspond to “high automation,” in which the system performs all driving functions, and the driver is expected to take control of the vehicle only in emergency situations. At autonomous driving level 5, the SAE classification standard may correspond to “full automation,” in which the system performs full driving functions without any aid from the driver including in emergency situations, and the driver is not expected to perform any driving functions other than determining the operating state of the system. Although the present disclosure may apply the SAE classification standard for autonomous driving classification, other classification methods and/or algorithms may be used in one or more configurations described herein.

One or more features associated with autonomous driving control may be activated based on configured autonomous driving control setting(s) (e.g., based on at least one of: an autonomous driving classification, a selection of an autonomous driving level for a vehicle, etc.). Based on one or more features (e.g., feature of identifying at least one abnormal battery cell, etc.) described herein, an operation of the vehicle may be controlled. The vehicle control may include various operational controls associated with the vehicle (e.g., autonomous driving control, sensor control, braking control, braking time control, acceleration control, acceleration change rate control, alarm timing control, forward collision warning time control, etc.).

One or more auxiliary devices (e.g., engine brake, exhaust brake, hydraulic retarder, electric retarder, regenerative brake, etc.) may also be controlled, for example, based on one or more features (e.g., feature of identifying at least one abnormal battery cell, etc.) described herein. One or more communication devices (e.g., a modem, a network adapter, a radio transceiver, an antenna, etc., that is capable of communicating via one or more wired or wireless communication protocols, such as Ethernet, Wi-Fi, near-field communication (NFC), Bluetooth, Long-Term Evolution (LTE), 5G New Radio (NR), vehicle-to-everything (V2X), etc.) may also be controlled, for example, based on one or more features (feature of identifying at least one abnormal battery cell, etc.) described herein.

Minimum risk maneuver (MRM) operation(s) may also be controlled, for example, based on one or more features (e.g., feature of identifying at least one abnormal battery cell, etc.) described herein. A minimal risk maneuvering operation (e.g., a minimal risk maneuver, a minimum risk maneuver) may be a maneuvering operation of a vehicle to minimize (e.g., reduce) a risk of collision with surrounding vehicles in order to reach a lowered (e.g., minimum) risk state. A minimal risk maneuver may be an operation that may be activated during autonomous driving of the vehicle when a driver is unable to respond to a request to intervene. During the minimal risk maneuver, one or more processors of the vehicle may control a driving operation of the vehicle for a set period of time.

Biased driving operation(s) may also be controlled, for example, based on one or more features (e.g., feature of identifying at least one abnormal battery cell, etc.) described herein. A driving control apparatus may perform a biased driving control. To perform a biased driving, the driving control apparatus may control the vehicle to drive in a lane by maintaining a lateral distance between the position of the center of the vehicle and the center of the lane. For example, the driving control apparatus may control the vehicle to stay in the lane but not in the center of the lane. The driving control apparatus may identify or determine a biased target lateral distance for biased driving control. For example, a biased target lateral distance may comprise an intentionally adjusted lateral distance that a vehicle may aim to maintain from a reference point, such as the center of a lane or another vehicle, during maneuvers such as lane changes. This adjustment may be made to improve the vehicle's stability, safety, and/or performance under varying driving conditions, etc. For example, during a lane change, the driving control system may bias the lateral distance to keep a safer gap from adjacent vehicles, considering factors such as the vehicle's speed, road conditions, and/or the presence of obstacles, etc.

One or more sensors (e.g., IMU sensors, camera, LIDAR, RADAR, blind spot monitoring sensor, line departure warning sensor, parking sensor, light sensor, rain sensor, traction control sensor, anti-lock braking system sensor, tire pressure monitoring sensor, seatbelt sensor, airbag sensor, fuel sensor, emission sensor, throttle position sensor, inverter, converter, motor controller, power distribution unit, high-voltage wiring and connectors, auxiliary power modules, charging interface, etc.) may also be controlled, for example, based on one or more features (e.g., feature of identifying at least one abnormal battery cell, etc.) described herein. An operation control for autonomous driving of the vehicle may include various driving control of the vehicle by the vehicle control device (e.g., acceleration, deceleration, steering control, gear shifting control, braking system control, traction control, stability control, cruise control, lane keeping assist control, collision avoidance system control, emergency brake assistance control, traffic sign recognition control, adaptive headlight control, etc.).

An autonomous driving level and/or autonomous driving activation/deactivation may also be controlled, for example, based on one or more features (e.g., feature of identifying at least one abnormal battery cell, etc.) described herein. A driving control apparatus may perform an autonomous driving level control (e.g., a change of an autonomous driving level, a change of a required user attentiveness, etc.) or cause deactivation of an autonomous driving operation. For example, by changing the required user attentiveness, the driver may be required to place his/her hands on the driving wheel more often (e.g., at least once in a threshold time period, such as five second, 30 seconds, 1 minute, etc.). By changing the required user attentiveness, the driver may be required to look ahead more often (e.g., at least once in a threshold time period, such as five second, 30 seconds, 1 minute, etc.). By changing the autonomous driving level, one or more video contents may not be displayed on a display of the vehicle.

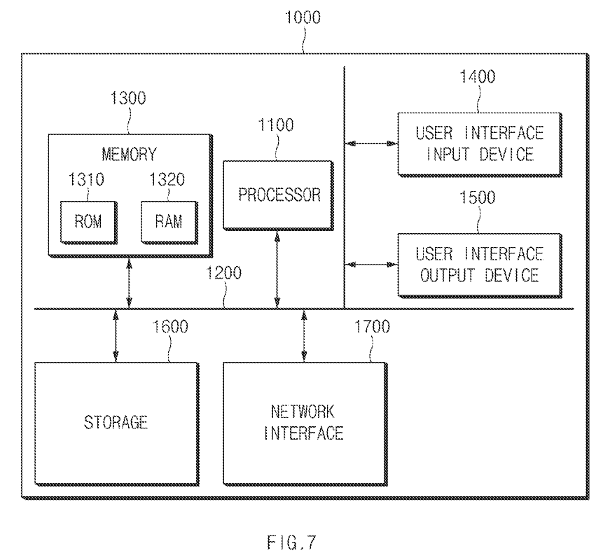

FIG. 7 is a block diagram illustrating a computing system for executing a battery diagnostic method.

Referring to FIG. 7, the above-mentioned battery diagnostic method may be implemented via a computing system 700. The computing system 700 may include at least one processor 720, a memory 730, a user interface input device 740, a user interface output device 750, storage 760, and a network interface 770, which are connected with each other through a system bus 710.

The processor 710 may be a central processing unit (CPU) or a semiconductor device that processes instructions stored in the memory 730 and/or the storage 760. The memory 730 and the storage 760 may include various types of volatile or non-volatile storage media. For example, the memory 730 may include a read only memory (ROM) 731 and a random access memory (RAM) 732.

Accordingly, the operations of the method or algorithm described in connection with the embodiment(s) disclosed in the specification may be directly implemented with a hardware module, a software module, or a combination of the hardware module and the software module, which is executed by the processor 710. The software module may reside on a storage medium (i.e., the memory 730 and/or the storage 760) such as a RAM, a flash memory, a ROM, an EPROM, an EEPROM, a register, a hard disc, a removable disk, and a CD-ROM. The exemplary storage medium may be coupled to the processor 710. The processor 710 may read out information from the storage medium and may write information in the storage medium. Alternatively, the storage medium may be integrated with the processor 710. The processor 710 and the storage medium may reside in an application specific integrated circuit (ASIC). The ASIC may reside within a user terminal. In another case, the processor 710 and the storage medium may reside in the user terminal as separate components.

According to an aspect of the present disclosure, a battery diagnostic apparatus may include a communication device that obtains current data of a battery in a first charging interval and a second charging interval different from the first charging interval and a controller that calculates a first capacity of each of a plurality of battery cells included in the battery based on the current data in the first charging interval, calculates a second capacity of each of the plurality of battery cells based on the current data in the second charging interval, and diagnoses whether abnormality occurs in the plurality of battery cells based on comparison between the first capacity and the second capacity.

According to an embodiment, the controller may calculate a first standardization value on the basis of an average value of the first capacities, may calculate a second standardization value on the basis of an average value of the second capacities, and may select a diagnosis target cell based on the first standardization value and the second standardization value.

According to an embodiment, the controller may select the battery cell, both the first standardization value and the second standardization value of which are greater than or equal to a reference value, as the diagnosis target cell and may diagnose whether the diagnosis target cell is abnormal based on comparison between the first capacity and the second capacity of the diagnosis target cell.

According to an embodiment, the controller may calculate a first relative value of the diagnosis target cell, the first relative value being relative to the average value of the first capacities, may calculate a second relative value of the diagnosis target cell, the second relative value being relative to the average value of the second capacities, and may compare the first relative value with the second relative value to diagnose whether the diagnosis target cell is abnormal.

According to an embodiment, the controller may diagnose that the abnormality occurs in the diagnosis target cell, if the first relative value is greater than the second relative value.

According to an embodiment, the controller may calculate the first capacity and the second capacity using Ah-counting based on the current data.

According to an embodiment, the first charging interval may be defined as a state of charge (SOC) range greater than the second charging interval.

According to another aspect of the present disclosure, a battery diagnostic method may include obtaining current data of a battery in a first charging interval and a second charging interval different from the first charging interval, calculating a first capacity of each of a plurality of battery cells included in the battery based on the current data in the first charging interval, calculating a second capacity of each of the plurality of battery cells based on the current data in the second charging interval, and diagnosing whether abnormality occurs in the plurality of battery cells based on comparison between the first capacity and the second capacity.

According to an embodiment, the battery diagnostic method may further include calculating a first standardization value on the basis of an average value of the first capacities, calculating a second standardization value on the basis of an average value of the second capacities, and selecting a diagnosis target cell based on the first standardization value and the second standardization value.

According to an embodiment, the selecting of the diagnosis target cell may include selecting the battery cell, both the first standardization value and the second standardization value of which are greater than or equal to a reference value, as the diagnosis target cell. The battery diagnostic method may further include diagnosing whether the diagnosis target cell is abnormal based on comparison between the first capacity and the second capacity of the diagnosis target cell.

According to an embodiment, the battery diagnostic method may further include calculating a first relative value of the diagnosis target cell, the first relative value being relative to the average value of the first capacities, calculating a second relative value of the diagnosis target cell, the second relative value being relative to the average value of the second capacities, and comparing the first relative value with the second relative value to diagnose whether the diagnosis target cell is abnormal.

According to an embodiment, the diagnosing of whether the diagnosis target cell is abnormal may include diagnosing that the abnormality occurs in the diagnosis target cell, if the first relative value is greater than the second relative value.

According to an embodiment, the battery diagnostic method may further include calculating the first capacity and the second capacity using Ah-counting based on the current data.

According to an embodiment, the first charging interval may be defined as a state of charge (SOC) range greater than the second charging interval.

According to another aspect of the present disclosure, a battery diagnostic system may include a battery including a plurality of battery cells, a sensor that obtains current data of the battery in a first charging interval and a second charging interval different from the first charging interval, and a battery diagnostic apparatus that diagnoses whether abnormality occurs in the plurality of battery cells.

According to an embodiment, the battery diagnostic apparatus may obtain the current data from the sensor, may calculate a first capacity of each of the plurality of battery cells based on the current data in the first charging interval, may calculate a second capacity of each of the plurality of battery cells based on the current data in the second charging interval, may calculate a first relative value of the first capacity and a second relative value of the second capacity, and may diagnose whether the abnormality occurs based on comparison between the first relative value and the second relative value.

According to an embodiment, the battery diagnostic apparatus may calculate the first capacity of each of the plurality of battery cells using Ah-counting based on the current data in a first voltage range which is common among voltage ranges of the plurality of battery cells in the first charging interval and may calculate the second capacity of each of the plurality of battery cells using the Ah-counting based on the current data in a second voltage range which is common among the voltage ranges of the plurality of battery cells in the second charging interval.

According to an embodiment, the battery diagnostic apparatus may calculate a first standardization value on the basis of an average value of the first relative values, may calculate a second standardization value on the basis of an average value of the second relative values, and may select the battery cell, both the first standardization value and the second standardization value of are greater than or equal to a relative value, as a diagnosis target cell.

According to an embodiment, the battery diagnostic apparatus may compare the first relative value of the diagnosis target cell with the second relative value of the diagnosis target cell to diagnose whether the diagnosis target cell is abnormal.

The present technology may provide the battery diagnostic apparatus for diagnosing whether an individual battery cell is abnormal during charging and the method thereof.

Furthermore, the present technology may provide the battery diagnostic apparatus for discriminating between an over-capacity cell due to a manufacturing deviation and an abnormal cell due to a leak current and the method thereof.

In addition, various effects ascertained directly or indirectly through the present disclosure may be provided.

The above description is merely an example of the technical idea of the present disclosure, and various modifications and variations may be made by one skilled in the art without departing from the essential characteristic of the present disclosure.

Accordingly, embodiment(s) disclosed in the present disclosure are intended not to limit but to explain the technical idea of the present disclosure, and the scope and spirit of the present disclosure is not limited by the above embodiment(s). The scope of protection of the present disclosure should be construed by the attached claims, and all the technical ideas in the range equivalent thereto should be construed as being included within the scope of the present disclosure.

What is claimed is:

1. A battery diagnostic apparatus for a vehicle, the battery diagnostic apparatus comprising:
a communication interface configured to obtain, via at least one sensor, first current data of a battery in a first charging interval and second current data of the battery in a second charging interval different from the first charging interval, wherein each of the first current data and the second current data is based on current flow measurements of a plurality of battery cells included in the battery; and
a controller configured to:
determine a first capacity of each of the plurality of battery cells based on the first current data in the first charging interval,
determine a second capacity of each of the plurality of battery cells based on the second current data in the second charging interval, and
generate, based on a comparison of the first capacities and the second capacities, a signal indicating at least one abnormal cell of the plurality of battery cells.

2. The battery diagnostic apparatus of claim 1, wherein the controller is configured to:
determine a first standardization value based on an average value of the first capacities;
determine a second standardization value based on an average value of the second capacities; and
select a diagnosis target cell based on the first standardization value and the second standardization value.

3. The battery diagnostic apparatus of claim 2, wherein the controller is configured to:
select, based on both the first standardization value and the second standardization value of an outlier cell of the plurality of battery cells being greater than or equal to a reference value, the outlier cell as the diagnosis target cell; and
diagnose whether the diagnosis target cell is abnormal based on a comparison between the first capacity and the second capacity of the diagnosis target cell.

4. The battery diagnostic apparatus of claim 2, wherein the controller is configured to:
determine a first relative value of the diagnosis target cell, the first relative value being relative to the average value of the first capacities;
determine a second relative value of the diagnosis target cell, the second relative value being relative to the average value of the second capacities; and
compare the first relative value with the second relative value to diagnose whether the diagnosis target cell is abnormal.

5. The battery diagnostic apparatus of claim 4, wherein the controller is configured to:
determine that the diagnosis target cell is an abnormal cell, based on the first relative value being greater than the second relative value, wherein a state of charge (SOC) of the battery during the first charging interval is higher than an SOC of the battery during the second charging interval.

6. The battery diagnostic apparatus of claim 1, wherein the controller is configured to:
determine the first capacities, using Ampere-hour counting, based on the first current data; and
determine the second capacities, using Ampere-hour counting, based on the second current data.

7. The battery diagnostic apparatus of claim 1, wherein state of charge (SOC) values of the first charging interval are greater than SOC values of the second charging interval.

8. A battery diagnostic method performed by a battery diagnostic apparatus, the battery diagnostic method comprising:
obtaining, via at least one sensor, first current data of a battery in a first charging interval and second current data of the battery in a second charging interval different from the first charging interval, wherein each of the first current data and the second current data is based on current flow measurements of a plurality of battery cells included in the battery;
determining a first capacity of each of the plurality of battery cells based on the first current data in the first charging interval;
determining a second capacity of each of the plurality of battery cells based on the second current data in the second charging interval; and
generating, based on a comparison of the first capacities and the second capacities, a signal indicating at least one abnormal cell of the plurality of battery cells.

9. The battery diagnostic method of claim 8, further comprising:
determining a first standardization value based on an average value of the first capacities;
determining a second standardization value based on an average value of the second capacities; and
selecting a diagnosis target cell based on the first standardization value and the second standardization value.

10. The battery diagnostic method of claim 9, wherein the selecting of the diagnosis target cell comprises:
selecting, based on both the first standardization value and the second standardization value of an outlier cell of the plurality of battery cells being greater than or equal to a reference value, the outlier cell as the diagnosis target cell, and
wherein the method further comprises:
diagnosing whether the diagnosis target cell is abnormal based on a comparison between the first capacity and the second capacity of the diagnosis target cell.

11. The battery diagnostic method of claim 10, further comprising:
determining a first relative value of the diagnosis target cell, the first relative value being relative to the average value of the first capacities;
determining a second relative value of the diagnosis target cell, the second relative value being relative to the average value of the second capacities; and
comparing the first relative value with the second relative value to diagnose whether the diagnosis target cell is abnormal.

12. The battery diagnostic method of claim 11, wherein the diagnosing of whether the diagnosis target cell is abnormal comprises:
determining that the diagnosis target cell is an abnormal cell, based on the first relative value being greater than the second relative value, wherein a state of charge (SOC) of the battery during the first charging interval is higher than an SOC of the battery during the second charging interval.

13. The battery diagnostic method of claim 8, further comprising:
determining the first capacities, using Ampere-hour counting, based on the first current data; and
determining the second capacities, using Ampere-hour counting, based on the second current data.

14. The battery diagnostic method of claim 8, wherein state of charge (SOC) values of the first charging interval are greater than SOC values of the second charging interval.

15. A battery diagnostic system for a vehicle, the battery diagnostic system comprising:
a battery including a plurality of battery cells;
a sensor configured to obtain first current data of the battery in a first charging interval and second current data of the battery in a second charging interval different from the first charging interval, wherein each of the first current data and the second current data is based on current flow measurements of the plurality of battery cells; and
a battery diagnostic apparatus configured to:
identify, based on the first current data, at least one first outlier cell of the plurality of battery cell;
identify, based on the second current data, at least one second outlier cell of the plurality of battery cell;
identify, based on a comparison between the first current data and the second current data, at least one abnormal cell, wherein each of the at least one abnormal cell is one of the at least one first outlier cell corresponding to one of the at least one second outlier cell; and
generate a signal indicating the at least one abnormal cell.

16. The battery diagnostic system of claim 15, wherein the battery diagnostic apparatus is configured to:
receive, from the sensor, the first current data and the second current data;
determine a first capacity of each of the plurality of battery cells based on the first current data;
determine a second capacity of each of the plurality of battery cells based on the second current data; and
identify, based on a comparison of the first capacities and the second capacities, the at least one abnormal cell.

17. The battery diagnostic system of claim 16, wherein the battery diagnostic apparatus is configured to:
determine a first relative value of the first capacity of an outlier cell and a second relative value of the second capacity of the outlier cell; and
diagnose whether the outlier cell is an abnormal cell based on a comparison between the first relative value and the second relative value.

18. The battery diagnostic system of claim 15, wherein the battery diagnostic apparatus is configured to:
determine a first capacity of each of the plurality of battery cells, using Ampere-hour counting, based on the first current data in a first voltage range which is common among voltage ranges of the plurality of battery cells in the first charging interval; and
determine a second capacity of each of the plurality of battery cells, using Ampere-hour counting, based on the second current data in a second voltage range which is common among voltage ranges of the plurality of battery cells in the second charging interval.

19. The battery diagnostic system of claim 16, wherein the battery diagnostic apparatus is configured to:
determine a first standardization value based on an average value associated with the first capacities;
determine a second standardization value based on an average value associated with the second capacities; and
select, based on both the first standardization value and the second standardization value of an outlier cell being greater than or equal to a relative value, the outlier cell as a diagnosis target cell.

20. The battery diagnostic system of claim 17, wherein the battery diagnostic apparatus is configured to:
compare the first relative value with the second relative value to diagnose whether the outlier cell is abnormal.
